(19) United States
(12) Patent Application Publication
(10) Pub. No.: US 2014/0290713 A1
(43) Pub. Date: Oct. 2, 2014

(54) SUNLIGHT RECEIVING DEVICE AND SUNLIGHT RECEIVING SYSTEM

(71) Applicant: FUJITSU LIMITED, Kawasaki-shi (JP)

(72) Inventor: Manabu KAI, Yokohama (JP)

(73) Assignee: FUJITSU LIMITED, Kawasaki-shi (JP)

(21) Appl. No.: 14/188,422

(22) Filed: Feb. 24, 2014

(30) Foreign Application Priority Data
Mar. 26, 2013 (JP) 2013-064943

(51) Int. Cl. H01L 31/05

(52) U.S. Cl. CPC H01L 31/05
USPC 136/244; 136/252

(57) ABSTRACT

A sunlight receiving device includes a substrate, and a plurality of resonators arranged on a surface of the substrate at certain intervals so as to form one of a plurality of loops, the plurality of loops partially bordering with each other, each one of the plurality of resonators having a length that resonates with sunlight of a certain wavelength, wherein energy of the sunlight is obtained via a resonator that belongs to one or more of the plurality of loops, the resonator being one of the plurality of resonators.

### CROSS-REFERENCE TO RELATED APPLICATION

This application is based upon and claims the benefit of priority of the prior Japanese Patent Application No. 2013-064943, filed on Mar. 26, 2013, the entire contents of which are incorporated herein by reference.

### FIELD

The embodiments discussed herein are related to a sunlight receiving device and a sunlight receiving system.

### BACKGROUND

A sunlight receiving device or a sunlight receiving system produces electrical energy from sunlight it receives. Sunlight has both properties as particles (that is, photons) and properties as a wave (that is, an electromagnetic wave).

When photons hit electrodes on a solar panel that utilizes sunlight properties as particles, electrons are knocked loose due to photoelectric effect and electrons in the solar panel move so as to compensate for those electrons to cause polarization. By making use of a potential difference, namely an electric battery, generated by the polarization, energy derived from sunlight may be utilized. Although varying depending on device and/or conditions, the reception efficiency of this kind of solar panel per unit area is only about 18%.

An example of a traditional technology that utilizes sunlight properties as a wave is to form an array antenna by connecting multiple resonators for receiving sunlight with a single feeding point in parallel through a line and adjust phase among the resonators to give directivity to a beam of the array antenna (see Japanese Laid-open Patent Publication No. 2009-171533, for example, for this point). In this technology, however, reception efficiency per unit area may be low for sunlight spanning a wide wavelength range because it merely makes a beam directional to thereby narrow the beam with an array antenna for sunlight in the visible light range.

Another example of a traditional technology based on sunlight properties as a wave is to form an array antenna that achieves desired directivity by connecting multiple resonators formed of spiral lines in series through a line (see, for example, Proceedings of ES2008, Energy Sustainability 2008-54016, “Solar nantenna electromagnetic collectors” (URL at the time of application, http://www.osti.gov/bridge/product.biblio.jsp?isit_id934544) for this point). Since this technology is designed specifically for sunlight in the infrared range and simply narrows a beam, reception efficiency per unit area may be low for sunlight in a wide wavelength range. Another possible concern is reduction in reception efficiency caused by heat generation due to conductor loss because individual resonators forming the array antenna are all connected by a line in series. Reduction in reception efficiency due to conductor loss would be large especially when an inexpensive conductor is used, as such a conductor has high resistivity.

### SUMMARY

According to an aspect of the invention, a sunlight receiving device includes a substrate, and a plurality of resonators arranged on a surface of the substrate at certain intervals so as to form one of a plurality of loops, the plurality of loops partially bordering with each other, each one of the plurality of resonators having a length that resonates with sunlight of a certain wavelength, wherein energy of the sunlight is obtained via a resonator that belongs to one or more of the plurality of loops, the resonator being one of the plurality of resonators.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates the configuration of a sunlight receiving device in an embodiment of the present disclosure;

FIG. 2 is a sectional view taken along line II-II in FIG. 1;

FIG. 3 is a diagram illustrating resonator arrangement;

FIG. 4 is a diagram illustrating resonator operation;

FIG. 5 illustrates another resonator arrangement;

FIG. 6 illustrates a sunlight receiving device with two loops formed without bordering each other;

FIG. 7 illustrates a sunlight receiving system in which multiple sunlight receiving devices are two-dimensionally arranged;

FIG. 8 illustrates a sunlight receiving system in which two sunlight receiving devices corresponding to different polarization directions are two-dimensionally arranged;

FIG. 9 illustrates a sunlight receiving system in which two sunlight receiving devices corresponding to different resonance wavelengths are two-dimensionally arranged;

FIG. 10 illustrates a sunlight receiving system in which multiple sunlight receiving devices are three-dimensionally arranged;

FIG. 11 is a side view of the sunlight receiving system illustrated in FIG. 10;

FIG. 12 illustrates a sunlight receiving system in which three sunlight receiving devices corresponding to different polarization directions are three-dimensionally arranged;

FIG. 13 illustrates a sunlight receiving system in which three sunlight receiving devices corresponding to different polarization directions are three-dimensionally arranged;

FIG. 14 is a side view of the sunlight receiving system illustrated in FIG. 13;

FIG. 15 is a top view of the sunlight receiving system illustrated in FIG. 13;

FIG. 16 illustrates a sunlight receiving system in which three sunlight receiving devices corresponding to different resonance wavelengths are three-dimensionally arranged;

FIG. 17 is a side view of the sunlight receiving system illustrated in FIG. 16;

FIG. 18 is a top view of the sunlight receiving system illustrated in FIG. 16;

FIG. 19 illustrates an application that uses multiple sunlight receiving devices; and

FIG. 20 illustrates a comparison of reception efficiency between an embodiment of the present disclosure and a traditional device.

### DESCRIPTION OF EMBODIMENTS

For improving the sun receiving device or receiving system, it is desired to improve the reception efficiency per unit of sunlight of a sunlight receiving device or system.

Embodiments of the present disclosure will be described with reference to the accompanying drawings from the following perspectives.

1. Sunlight receiving device

1.1 Basic structure

1.2 Basic operation

2. Two-dimensional sunlight receiving system

2.1 Two-dimensional arrangement

2.2 Polarization

2.3 Wavelength/frequency

3. Three-dimensional sunlight receiving system

3.1 Three-dimensional arrangement

3.2 Polarization

3.3 Wavelength/frequency

4. Applications

4.1 Tree structure

4.2 Reception efficiency

The following description will make reference to drawings, throughout which similar elements are denoted with the same reference numerals or characters.

### 1. Sunlight Receiving Device

<<1.1 Basic Structure>>

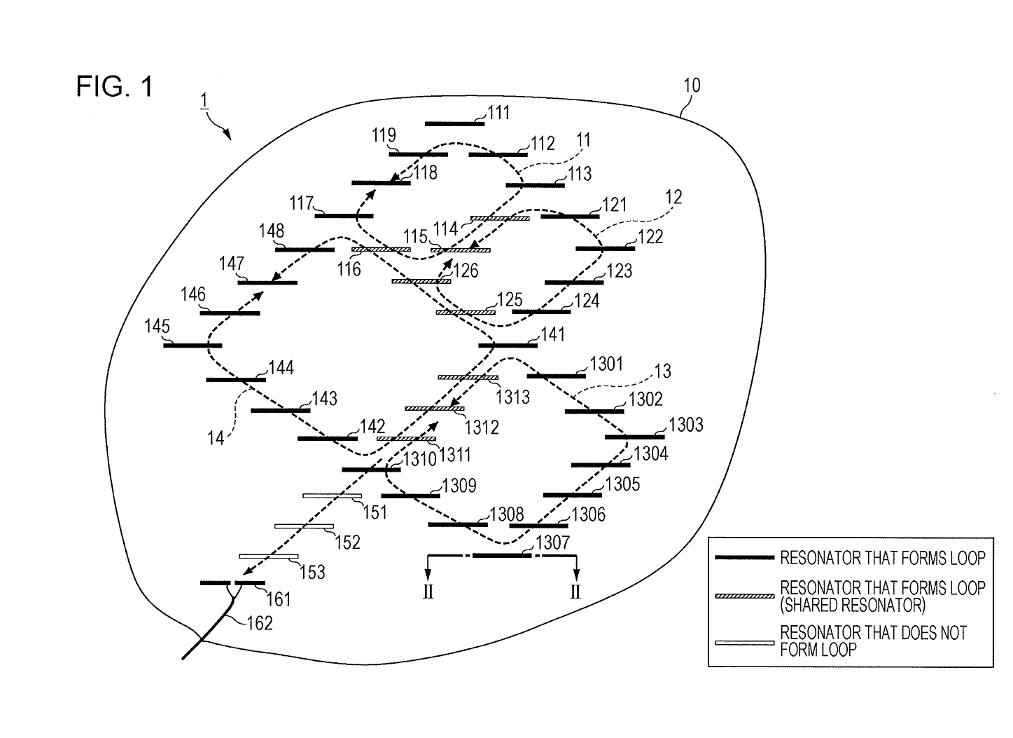

FIG. 1 illustrates the configuration of a sunlight receiving device 1 according to an embodiment of the present disclosure. The sunlight receiving device 1 at least includes a substrate 10, and multiple resonators 111 to 119, 121 to 126, 1301 to 1313, and 141 to 148. The resonators 111 and so on are arranged at predetermined intervals so that they form multiple loops 11 to 14 which partially border each other. Note that the resonators 111 and so on are physically present on a surface of the substrate; whereas the loops 11 to 14 are not lines that are physically present. The loops 11 to 14 are thus represented by dashed lines. The sunlight receiving device 1 further includes resonators 151 to 153 on the substrate 10 that are arranged at predetermined intervals between a resonator 1310, which is one of the resonators forming loops 13 and 14, and a power feeding unit 161. A feed line 162 is connected to the power feeding unit 161, and two conductors making up the feed line 162 may be connected to the inner and outer conductors of a coaxial cable, for example. Energy gained from sunlight is output to outside the sunlight receiving device 1 by way of the power feeding unit 161 and feed line 162 and fed to a rectifier and the like not illustrated.

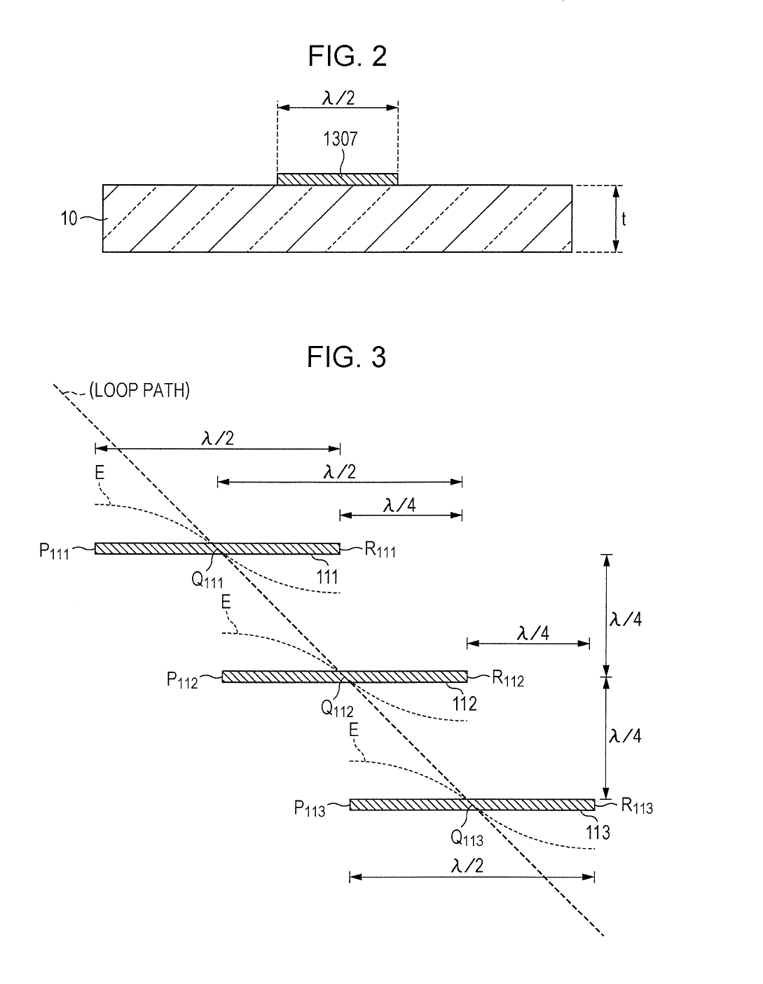

FIG. 2 is a sectional view taken along line II-II in FIG. 1. Although the sectional view illustrates a resonator 1307 and the substrate 10 as an example, a similar structure exists for any resonator present on the substrate 10 surface.

The substrate 10 may be made of any material having insulation properties. As an example, the substrate 10 may be made of a transparent dielectric substrate which transmits sunlight. The substrate 10 may be formed of transparent plastic material such as polycarbonate, for example. When multiple sunlight receiving devices 1 are used in a stacked form as discussed below, the substrate 10 is preferably transparent; when the sunlight receiving device 1 is used singly, it is not requisite that the substrate 10 be transparent. The substrate 10 may have any thickness t appropriate for usage; as an example, it has a thickness ranging from about 0.1 mm to several millimeters. The substrate 10 therefore may be a flexible substrate having a thickness of about 0.1 mm or a rigid substrate having a thickness of about 3 mm, for example. In general, the thickness t of the substrate 10 is preferably small in terms of reducing the weight of the sunlight receiving device 1. Conversely, in terms of making the sunlight receiving device 1 rigid or hard, the thickness t of the substrate 10 is preferably large, but the sunlight receiving device 1 becomes heavier as the thickness increases. The surface of the substrate 10 is typically planar, though embodiments thereof are not limited to a planar surface and a surface with any appropriate profile may be adopted. For example, the surface of the substrate may have asperities or irregularities on it so that resonators on the substrate 10 are able to resonate with light from the sun, whose position varies with time. In terms of effectively exposing the resonators on the substrate 10 to sunlight, the sunlight receiving device 1 illustrated in FIG. 1 may be moved or rotated so that it is directed toward the sun.

Note that while a resonator 1307 is formed on one surface of the substrate 10 (the top or front surface) in the structure illustrated in FIG. 2, no conductive layer such as a ground plane (a ground plate, or GND) is provided on the other surface (the underside or backside). In this respect, this embodiment differs from a micro strip line having a ground plane on the underside and a transmission path on the top surface. This is because such a ground plane on the underside is not desired as the resonators 111 and the like on the substrate 10 only have to resonate with sunlight in the embodiment illustrated in FIG. 1.

As illustrated in FIGS. 1 and 2, the resonator 1307 is provided on the surface of the substrate 10. As mentioned above, a similar structure exists for any resonator present on the substrate 10 surface, though the description here takes the resonator 1307 as an example. In other words, the resonators 111 and so on in this embodiment all have the same shape, length, thickness, and width.

While sunlight contains electromagnetic waves of certain wavelengths and certain polarizations, the sunlight receiving device 1 is designed to produce energy from at least sunlight of a particular wavelength. Specifically, the resonator 1307 has a length (λ/2) half the target wavelength (namely fundamental resonance wavelength) λ, of sunlight (an electromagnetic wave). As described later, it is also possible to produce energy from sunlight of a particular polarization instead of sunlight of a particular wavelength (this is described in Sections 2.2 and 3.2). Accordingly, the target wavelength λ of sunlight may be any appropriate value; for example, it may be a certain wavelength ranging from ultraviolet (400 nm or less) to infrared (760 nm or more), or a wavelength in the visible light range (360 nm to 830 nm), which has relatively stronger energy. Description on operation below assumes that the resonators are designed to have a length of 300 nm (λ/2=600/2 nm) as an example.

The length of the resonator 1307 is a parameter that determines the operation of the sunlight receiving device 1 (specifically, how resonance occurs), whereas the width and thickness of the resonator 1307 are not such parameters. As the width and thickness of the resonators 111 and so on are therefore not relatively important, the resonators 111 and so on are depicted as segments in figures including FIG. 1. The resonator 1307 may have any width and thickness; by way of example, the resonator 1307 may have a width of 30 nm and a thickness from 10 μm to 40 μm.

The resonator 1307 may be formed of any appropriate electrically conductive material as long as it resonates when receiving sunlight. The resonator 1307 may be made of such materials as gold (Au), silver (Ag), aluminum (Al), copper (Cu), and platinum (Pt), for instance. The resonator 1307 may be formed by etching a metal film deposited on the substrate 10, for example. As such film formation techniques are well known in the art, they are not further described herein.

Referring back to FIG. 1, the multiple resonators 111 and so on are arranged at predetermined intervals so that they form multiple loops 11 to 14 which partially border each other. A first loop 11 is formed by nine resonators 111 to 119. A second loop 12 is formed by eight resonators 121 to 126, 115, and 114. In this case, resonators 114 and 115 are members of both the first loop 11 and the second loop 12. Such a resonator that is shared for formation of more than one loop is referred to as “shared resonator” for the purpose of description. A third loop 13 is formed by 13 resonators 1301 to 1313. A fourth loop 14 is formed by 14 resonators 141, 1313, 1312, 1311, 142 to 148, 116, 126, and 125. The resonator 116 is a shared resonator for the first loop 11 and the fourth loop 14. Resonators 125, 126 are shared resonators for the second loop 12 and the fourth loop 14. Resonators 1313, 1312, and 1311 are shared resonators for the third loop 13 and the fourth loop 14.

FIG. 3 is a diagram illustrating how resonators are arranged. Although three resonators 111 to 113 forming the first loop 11 in FIG. 1 are taken as an example for the purpose of description, a similar relationship holds for other neighboring resonators. Although the path of the loop 11 is represented by a dashed line in FIG. 3, such a line is not physically present. Neighboring resonators are arranged in such a positional relationship that causes coupling between them with sunlight of a predetermined wavelength. By way of example, each of the resonators 111 to 113 has a length (λ/2) equal to half the target wavelength (or fundamental resonance wavelength) of sunlight. More generally, when the length L of a resonator is a half-integer multiple of a certain wavelength (that is, when L=λ₁/2, λ₂3/2, λ₃5/2, . . . ), the resonator resonates with sunlight of that wavelength (λ₁, λ₂, λ₃, . . . ). Also, when sunlight is incident on a resonator having length L of λ₁/2, the resonator also resonates with sunlight of wavelengths λ₁/3, λ₁/5, λ₁/7, . . . in addition to λ₁. In short, a resonator having a length of λ₁/2 resonates with sunlight having a wavelength of λ₁/(2n+1) (n=0, 1, 2, . . . ). Herein, such wavelength λ₁ is referred to as “fundamental resonance wavelength”, “target wavelength (of sunlight)”, or where there is no possibility of confusion, just “wavelength”. Further, a resonator having a length L of λ₁/2 also resonates at wavelengths in the vicinity of λ₁. “Vicinity” means±20% (0.8λ₁≦wavelength≦1.2λ₁) herein, though a different range such as ±10% (0.9λ₁≦wavelength≦1.1λ₁) may be used. To summarize, a resonator having a length L of λ₁/2 resonates at both a wavelength of λ₁/(2n+1), which is an odd submultiple of the fundamental resonance wavelength λ1, and wavelengths in the vicinity of λ₁. Sunlight of wavelength λ₁/(2n+1) or a wavelength in the vicinity of λ₁ is referred to as “resonance wavelength” because such sunlight causes resonance of a resonator having a length of λ₁/2. Also, a frequency corresponding to “fundamental frequency λ₁” is referred to as “fundamental resonance frequency f₁” (f₁=c/λ₁). Frequencies corresponding to the “resonance wavelength” (λ₁/(2n+1) and in the vicinity of λ₁) are referred to as “resonance frequencies” (c(2n+1)/λ₁ and in the vicinity of f1), where c represents the speed of light.

While specific operations will be described later, neighboring resonators 111, 112 formed on the substrate 10 are arranged in parallel with each other in a positional relationship in which they are shifted from each other by λ/4, that is, half their length (or one quarter-wavelength) as illustrated in FIG. 3. The neighboring resonators 111, 112 are also arranged in parallel being separated from each other by a distance equal to half their length (or one quarter-wavelength) λ/4. Neighboring resonators 112, 113 are also in a similar positional relationship. Although λ/4 is optimal, neighboring resonators will effectively couple with one another even with some deviation (±20% for example).

Referring back to FIG. 1, the sunlight receiving device 1 also includes resonators 151 to 153 on the substrate 10 which are arranged at predetermined intervals between the resonator 1310, which forms loops 13 and 14, and the power feeding unit 161. The resonators 151 to 153 differ from the resonators 111 and so on in that they do not form loops, but the resonators 151 to 153 are also arranged in such a positional relationship as illustrated in FIG. 3 like resonators 111 and so on.

<<1.2 Basic Operation>>

The operation of the sunlight receiving device 1 will be described with reference to FIGS. 1, 3, and 4. For the purpose of description, assume that the sunlight receiving device 1 is designed to have a fundamental resonance wavelength λ, of 600 nm. Accordingly, the resonators 111 and so on each have a length of λ/2=300 nm. When sunlight is incident on the sunlight receiving device 1, the resonators 111 and so on resonate with sunlight of the wavelength of λ/(2n+1) and wavelengths in the vicinity of λ (n=0, 1, 2, . . . ).

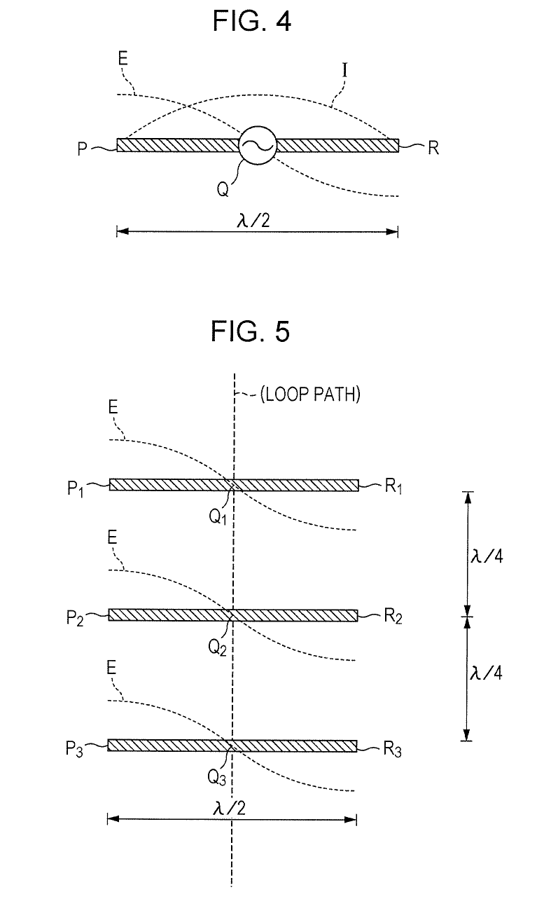

FIG. 4 qualitatively illustrates current distribution I and the level of electric field E in the length direction when a resonator resonates in fundamental mode. For the sake of illustration, the ends of the resonator are denoted by P and R, and the center of the resonator is denoted by Q. In this resonance state, current distribution I is largest in the center Q of the resonator and 0 at the ends P, R. Conversely, the level of electric field E is largest at the ends P, R of the resonator and 0 in the center Q. It follows that a resonator in resonance state is equivalent to a dipole antenna with a feeding point positioned in the center Q of the resonator. Describing this more generally, since a resonator having a length of λ/2 resonates with sunlight of the wavelength of λ/(2n+1) and wavelengths in the vicinity of λ (n=0, 1, 2, . . . ), the resonate has resonance state not only in fundamental mode but in higher mode. In higher mode, it is still true that (1) current distribution I is largest in the center Q of the resonator and 0 at the ends P, R, and that (2) electric field E is largest at the ends P, R of the resonator and 0 in the center Q.

Referring to FIG. 3, the level of electric field E in resonance state in fundamental mode is qualitatively illustrated for each of resonators 111 to 113. As illustrated, neighboring resonators are arranged in parallel with each other in a positional relationship in which they are shifted from each other by λ/4 (one half of the resonator length) and separated at a distance of λ/4 (one half of the resonator length). As in FIG. 4, the ends of the resonator are denoted by Pi, Ri, and the center of the resonator is denoted by Qi (where i=111, 112, or 113). The electric field E is largest at the end P112 of the resonator 112, and the distance between the end P112 and the center Q111 of the resonator 111 is only λ/4 (one half of the resonator length). Therefore, the large electric field E (namely voltage) at the end P111 strongly effects the center Q111, which further helps the center Q111 serve as feeding point.

Although the above description only discusses the effect exerted from the end P112 to the center Q111, there are also effects from other ends to the center, such as the effect exerted from the end R111 to the center Q112, effect exerted from the end P113 to the center Q112, and effect exerted from the end R113 to the center Q112. Although resonators that affect a certain resonator are theoretically not limited to neighboring resonators, effect from neighboring resonators is considered herein because effect from neighboring resonators is strongest.

From the viewpoint of electric field E level, as the distance between resonators, that is, the distance between the end P112 and the center Q111 is shorter, the electric field E has stronger effect on the center Q111. In order to transfer energy between neighboring resonators while they resonate at fundamental resonance wavelength λ, however, the neighboring resonators is disposed preferably in parallel at a certain distance (λ/4 in the examples illustrated in FIGS. 3 and 5) from each other. The resonator arrangement illustrated in FIG. 3 is preferable in terms of enhancing coupling between neighboring resonators, but the way of arranging resonators is not limited to the positional relationship illustrated in FIG. 3.

FIG. 5 illustrates another example of resonator arrangement. In this example, instead of being shifted from each other, neighboring resonators are arranged in alignment with each other in parallel. In the illustrated example, the line representing the loop path intersects with the resonators at an angle of 90 degrees. In the example in FIG. 3, in contrast, the line representing the loop path intersects the resonators at an angle of 45 degrees. Also in the case of FIG. 5, electric field E (that is, voltage), which is largest at the end P2 for example, affects the center Q1, helping the center Q1 serve as feeding point. The distance between the end P2 at which the electric field E is largest and the center Q1 which is affected by the electric field E is longer than the shortest distance between resonators (λ/4 in the illustrated example), however. Thus, though it is a possible arrangement of neighboring resonators, the resonator arrangement illustrated in FIG. 5 results in weaker coupling than the example in FIG. 3. Also in the case of FIG. 5, the center of a resonator is affected by the ends of the neighboring resonators, but there are other effects in addition to the effect exerted on the center Q1 from the end P2. Specifically, there are the effect exerted from the end P1 to the center Q2, effect exerted from the end R1 to the center Q2, effect exerted from the end P2 to the center Q1 (mentioned above), effect exerted from the end R2 to the center Q1, effect exerted from the end P2 to the center Q3, effect exerted from the end R2 to the center Q3, effect exerted from the end P3 to the center Q2, and effect exerted from the end R3 to the center Q2.

When two resonators are positioned side by side at a certain spacing (λ/4 for example), whether in the manner illustrated in FIGS. 3 and 5 or otherwise, the neighboring two resonators become coupled and energy is transferred from one resonator to the other resonator. Even when there are the third, fourth, and further resonators, energy from sunlight of a resonance wavelength (resonance frequency) is transferred to those resonators in sequence. Accordingly, when multiple resonators are arranged in one loop or closed curve at certain intervals (for example, λ/4), energy continues to circulate through the loop (energy continues to be transferred between neighboring resonators), resulting in energy from sunlight of the resonance wavelength being accumulated in the loop.

In relation to energy transfer between neighboring resonators, operation of a shared resonator in the sunlight receiving device 1 illustrated in FIG. 1 will be considered. In the case illustrated in FIG. 1, resonators 114, 115, 116, 125, 126, 1311, 1312, and 1313 are shared resonators. As an example, energy that continues to circulate through the first loop 11 (energy that continues to be transferred between neighboring resonators) is also transferred to the second loop 12 via shared resonators 114 and 115. That is, part of energy circulating through the first loop 11 is distributed to the neighboring second loop 12 via shared resonators 114, 115. Among shared resonators, a shared resonator that neighbors a non-shared resonator may also be referred to as “branch resonator”. In the example illustrated in FIG. 1, resonators 114, 116, 125, 1313, and 1311 are branch resonators.

The remaining energy continuing to circulate through the first loop 11 flows round the first loop 11 and is distributed to the second loop 12 again from shared resonators via branch resonators. Repeated occurrence of this action moves the energy received by the first loop 11 to the second, third, and fourth loops 12, 13, and 14. As four loops are formed in the example illustrated in FIG. 1, produced energy continues to circulate through the four loops 11 to 14 so that energy produced from sunlight is accumulated.

Next, a path that does not form a loop (non-looping path) will be considered. In a case where resonators are arranged at certain intervals (λ/4 for example) along a non-looping path, energy is still transferred between resonators along the path. When the energy reaches the resonator at the open end (Open) of the path, however, all or part of the energy is radiated from the open end (Open). For this reason, resonators have to be arranged so as to form a closed loop or a closed curve in terms of accumulating produced energy without loss. Meanwhile, resonators arranged along a non-loop-forming path may be utilized for fetching energy. Thus, in the example illustrated in FIG. 1, one or more (three in the illustrated example) resonators are arranged at certain intervals so as not to form a loop between the resonator 1310 and the power feeding unit 161 (in the example in FIG. 1, resonators are arranged in the manner described in FIG. 3, for example). Although resonators 151 to 153 are provided such that they do not form a loop in the example in FIG. 1, resonators arranged along a non-looping path are not requisite for fetching energy. For example, the power feeding unit 161 may be disposed so as to neighbor the resonator 1307, which belongs to the third loop 13 of FIG. 1.

Although not illustrated in FIG. 1, a rectifier for converting high-frequency alternating-current energy to direct-current energy is connected to one end of the feed line 162, which is connected at the other end to the power feeding unit 161, so that solar energy may be produced as direct-current energy. The rectifier is not requisite however; energy may be supplied to other devices in the form of alternating-current energy.

In terms of receiving sunlight of a specific wavelength and storing and fetching energy, a single loop formed by multiple paths may be enough. In terms of receiving more sunlight, however, it is preferable that a large number of resonators be arranged. For example, resonators are preferably arranged so as to form dense small loops. That is, it is preferable to arrange multiple loops that border each other in the form of mesh, grid, or leaf veins and arrange resonators along those loops at certain intervals. It is also technically possible to form multiple loops on the substrate 10 so as not to border each other.

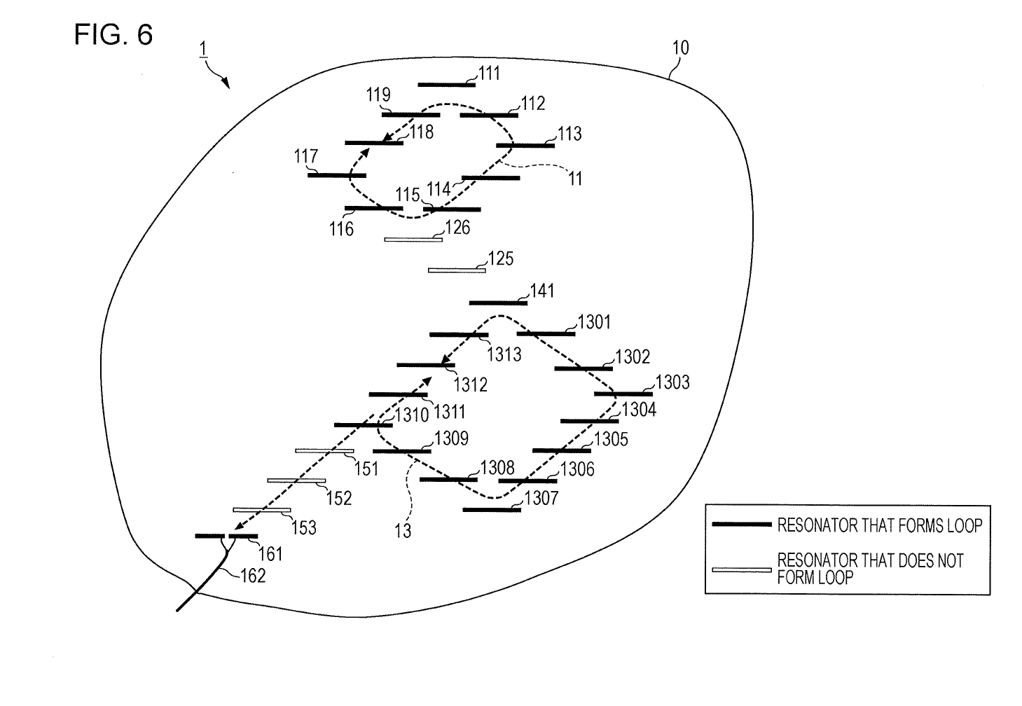

FIG. 6 illustrates a case where only two loops, the first loop 11 and the third loop 13, from the four loops illustrated in FIG. 1 are present. In the example of FIG. 6, the first loop 11 does not border the third loop 13 at all. In this case, in order to transfer the energy received and accumulated in the first loop 11 up to the power feeding unit 161, the energy has to go through resonators 126 and 125, which do not form a loop, the third loop 13, and resonators 151, 152, 153, which do not form a loop. Since resonators that form loops accumulate energy in the loops in the sunlight receiving device 1, resonators forming loops contribute to the sunlight reception efficiency per unit area. In contrast, resonators 126, 125, 151, 152, and 153 which do not form a loop are only involved with energy transfer and do not contribute to per-unit-area reception efficiency. Therefore, in terms of improving per-unit-area reception efficiency, it is desirable that the proportion of non-loop-forming resonators to the all resonators on the substrate is small. In the example illustrated in FIG. 6, there are as many as five resonators (17.9%) that do not form a loop out of the total of 28 resonators. Meanwhile in the example in FIG. 1, there are only three (7.69%) non-loop-forming resonators out of the total of 39 resonators. In terms of improving reception efficiency per unit area, it is desirable to arrange resonators such that multiple loops border each other and non-loop-forming resonators are minimized as in the example in FIG. 1, rather than the example in FIG. 6. Also, by forming multiple loops so that they border each other, resonators responsible only for energy transfer between loops (that is, resonators that do not form loops) are preferably not provided. This is because a resonator positioned at a border with a neighboring loop is a “shared resonator” as mentioned above and such a resonator is able to serve both to accumulate and transfer energy.

### 2. Two-Dimensional Sunlight Receiving System

<<2.1 Two-Dimensional Arrangement>>

The sunlight receiving device illustrated in FIG. 1 may be used singly or multiple such sunlight receiving devices may be used in combination. Various embodiments for such combination will be described below. Sunlight receiving devices to be combined may be the same or different.

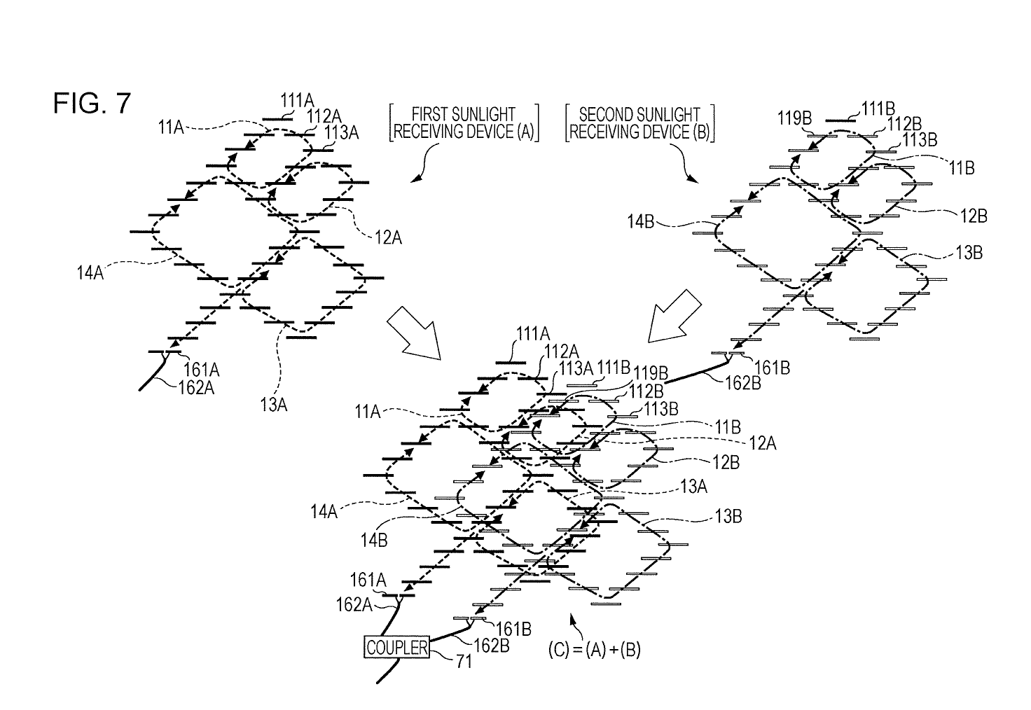

FIG. 7 illustrates a sunlight receiving system that combines two sunlight receiving devices of the type illustrated in FIG. 1. For the purpose of description, the two sunlight receiving devices will be referred to as a first sunlight receiving device (A) and a second sunlight receiving device (B). In the illustrated example, the two sunlight receiving devices (A) and (B) are arranged on the same planar surface. Since resonators are provided on a substrate, “the same planar surface” may also be expressed as “the same substrate”. Alternatively, the two sunlight receiving devices (A) and (B) may be described as being present at heights that are substantially equal in vertical direction.

First, as illustrated in the upper left and right in FIG. 7, the two sunlight receiving devices (A) and (B) may coexist without overlapping at all and electric power from them may be merged together. In this case, however, the entire sunlight receiving system occupies a large area, which is not preferable from the viewpoint of improvement in reception efficiency per unit area. Meanwhile, resonators and the like are not formed in an area defined by each loop included in the sunlight receiving device 1 of the type illustrated in FIG. 1. It is thus not possible to receive sunlight incident in an area defined by a loop and produce energy from it. This leads to the idea of making the whole or part of at least one loop of the second sunlight receiving device (B) be included in the area defined by at least one loop of the first sunlight receiving device (A). This may increase the density of resonators forming loops and improve reception efficiency per unit area.

In the example illustrated in the lower portion of FIG. 7, a second loop 12A of the first sunlight receiving device (A) is positioned so as to substantially coincide with a first loop 11B of the second sunlight receiving device (B). Also in the example illustrated in the lower portion of FIG. 7, a fourth loop 14B of the second sunlight receiving device (B) is positioned so as to partially overlap the third and fourth loops 13A, 14A of the first sunlight receiving device (A). Although the first and second sunlight receiving devices (A) and (B) overlap only partially in the illustrated example, they may entirely overlap. As mentioned above, neighboring resonators included in the first sunlight receiving device (A) (111A, 112A, 113A for example) are arranged such that large coupling occurs between them (the arrangement illustrated in FIG. 3 is employed for instance). Similarly, neighboring resonators included in the second sunlight receiving device (B) (111B and 119B for example) are also arranged such that large coupling occurs between them (the arrangement illustrated in FIG. 3 is employed for instance). In the example illustrated in the lower portion of FIG. 7, resonator 113A of the first sunlight receiving device (A) is positioned between neighboring resonators 111B and 119B of the second sunlight receiving device (B). The resonator 113A is the resonator closest to resonators 111B and 119B, but coupling with resonator 111B is zero or small if any. Coupling becomes large when resonators are arranged at a certain spacing (λ/4 for example) like resonators 111B and 119B, and energy is transferred between resonators when arranged in such a manner. If resonators are not arranged at such a spacing, on the contrary, energy will not be transferred even if the distance between resonators is short. This means that substantially no energy transfer occurs between resonator 113A and resonator 111B. Similarly, substantially no energy transfer occurs between resonator 113A and resonator 119B. While description here refers to resonators 111B, 119B, and 113A, what is described above is also true for any resonators that would be in proximity of each other when multiple sunlight receiving devices are stacked.

Energy from sunlight accordingly is not communicated between the first and the second sunlight receiving devices (A) and (B) but transferred only within the individual sunlight receiving devices (A) and (B), and power from the first and second sunlight receiving devices (A) and (B) is separately fed to the coupler 71 and merged therein. This may draw higher power from the coupler 71 than when the first or the second sunlight receiving device (A) or (B) is present singly. In this example, all resonators are present in an area smaller than when the first and second sunlight receiving devices (A) and (B) coexist without overlapping each other, which is preferable in terms of improving per-unit-area reception efficiency.

Although not illustrated in FIG. 7, a rectifier for converting high-frequency alternating-current energy to direct-current energy is coupled to the coupler 71, which is coupled with power feeding units 161A and 161B, so that solar energy may be produced as direct-current energy. The rectifier is not requisite however; energy may be supplied to other devices in the form of alternating-current energy.

While only two sunlight receiving devices are combined in the example of FIG. 7 for simplifying descriptions, any number of sunlight receiving devices may be combined.

Although not disclosed in Japanese Laid-open Patent Publication No. 2009-171533 or Proceedings of ES2008, Energy Sustainability 2008-54016, “Solar antenna electro magnetic collectors”, it is conceivable to improve reception efficiency by stacking two array antennas having multiple resonators connected in parallel, such as described in Japanese Laid-open Patent Publication No. 2009-171533, according to the above-described embodiment. In the scheme of Japanese Laid-open Patent Publication No. 2009-171533, however, there are as many wired lines connecting resonators in parallel as the number of resonators and the wired lines of one array antenna hide the other array antenna, so reception efficiency would not improve at least by such an overlap.

Another conceivable way to improve reception efficiency is to stack two array antennas having resonators connected in series, such as illustrated in the above-cited document “Solar antenna electro magnetic collectors”, according to the above-described embodiment. Disadvantageously, in the above-cited document “Solar antenna electro magnetic collectors”, each resonator having an intricate spiral shape occupies a larger area than a simple segment and also wired lines for serial connection are present. Hence, when two array antennas disclosed in the above-cited document “Solar antenna electro magnetic collectors” are stacked, the resonators and wired lines of one array antenna again hide the other array antenna, so reception efficiency would not improve at least by such an overlap. Besides, because resonators are connected in series by wired lines in the array antenna described in the above-cited document “Solar antenna electro magnetic collectors”, conductor loss becomes large and part of successfully received sunlight is wasted for heat generation associated with conductor loss, which is not preferable from the viewpoint of reception efficiency improvement and the like either.

<<2.2 Polarization>>

Sunlight randomly contains electromagnetic waves of different polarization directions (or polarized waves). A resonator having a shape of a segment as illustrated in FIG. 1 or 7 resonates with a linearly-polarized wave that has a resonance wavelength and whose polarization direction is parallel with the length direction of the segment. In general, a linearly-polarized wave refers to an electromagnetic wave for which the amplitude direction of an electric or magnetic field is a fixed direction. Such a resonator therefore is not able to fully extract energy from sunlight (an electromagnetic wave) whose polarization direction is different from the length direction. This leads to the idea of extracting energy from sunlight of different polarizations by combining multiple sunlight receiving devices corresponding to different resonator polarization directions.

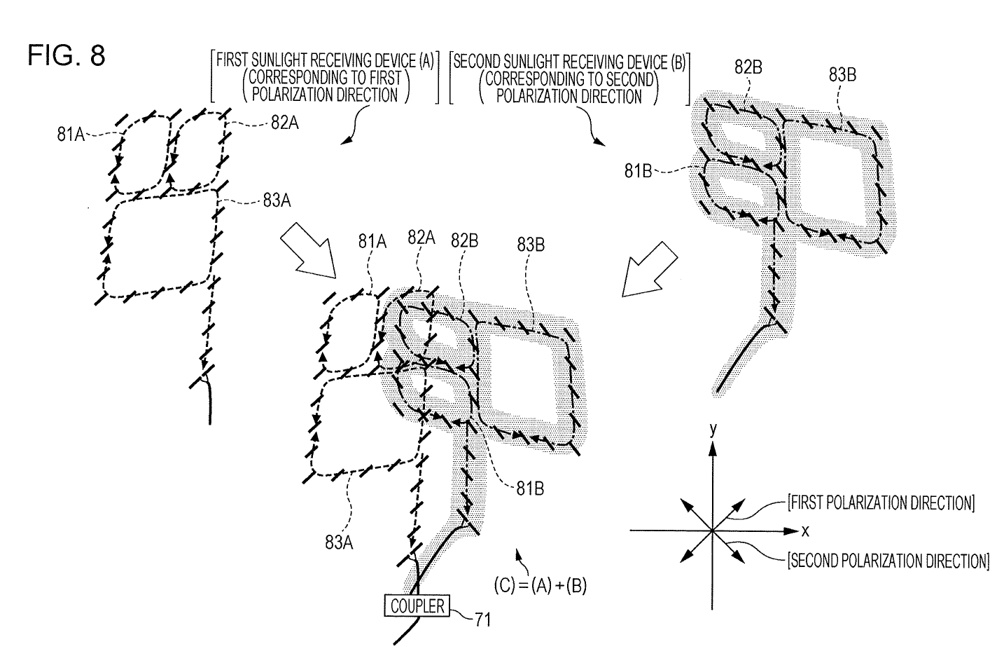

FIG. 8 illustrates a sunlight receiving system in which two sunlight receiving devices corresponding to different polarization directions are combined. In the illustrated example, a first sunlight receiving device (A) which resonates with electromagnetic wave components whose polarization direction is a first direction and a second sunlight receiving device (B) which resonates with electromagnetic wave components whose polarization direction is a second direction are arranged on the same planar surface. Since resonators are provided on a substrate, “the same planar surface” may also be expressed as “the same substrate”. Alternatively, the two sunlight receiving devices (A) and (B) may be described as being present at heights that are substantially equal in vertical direction. Although the first and second directions are orthogonal to each other in the illustrated example, they do not have to be orthogonal in general. The first sunlight receiving device (A) resonates with electromagnetic waves with their polarization direction being the first direction and is able to derive energy from it. The first sunlight receiving device (A) however is not able to derive energy from electromagnetic waves having a polarization direction orthogonal to the first direction. In contrast, the second sunlight receiving device (B) resonates with electromagnetic waves whose polarization direction is the second direction different from the first direction and is able to derive energy from it. Therefore, part of energy that may not be derived by first sunlight receiving device (A) may be derived by the second sunlight receiving device (B).

First, as illustrated in the upper left and right in FIG. 8, the two sunlight receiving devices (A) and (B) corresponding to different polarization directions may coexist without overlapping each other at all and power produced by them may be merged. In this case, however, the area occupied by the entire sunlight receiving system becomes large, which is not preferable from the viewpoint of improvement in reception efficiency per unit area. Meanwhile, resonators and the like are not formed in an area defined by each loop included in a sunlight receiving device such as the one illustrated in FIG. 1. It is thus not possible to receive sunlight incident in an area defined by a loop and produce energy from it. This leads to the idea of making the whole or part of at least one loop of the second sunlight receiving device (B) be included in the area defined by at least one loop of the first sunlight receiving device (A). This may increase the density of resonators forming loops and improve reception efficiency per unit area.

For the purpose of description, assume that multiple resonators included in the first sunlight receiving device (A) are provided on a substrate at predetermined intervals along a first loop 81A, a second loop 82A, and a third loop 83A. The second sunlight receiving device (B) is equivalent to the first sunlight receiving device (A) as turned 90 degrees to the left and is modified to route energy to the outside from a branch resonator belonging to the first loop 81B and the third loop 83B. Consequently, the polarization directions for which the two sunlight receiving devices (A) and (B) resonate differ from each other by 90 degrees.

In the example illustrated in the lower portion of FIG. 8, the second loop 82A of the first sunlight receiving device (A) partially overlaps the first loop 81B and the second loop 82B of the second sunlight receiving device (B). The third loop 83A of the first sunlight receiving device (A) also partially overlaps the first loop 81B of the second sunlight receiving device (B). The first and second sunlight receiving devices (A) and (B) resonate in different polarization directions. Energy from sunlight accordingly is not communicated between the first and the second sunlight receiving devices (A) and (B) but transferred only within the individual sunlight receiving devices (A) and (B), where power produced by the first and second sunlight receiving devices (A) and (B) is separately fed to the coupler 71 and merged therein. This may draw higher power from the coupler 71 than when the first or the second sunlight receiving device (A) or (B) is present singly. In this example, all resonators are present in an area smaller than when the first and second sunlight receiving devices (A) and (B) coexist without overlapping each other, which is preferable in terms of improving per-unit-area reception efficiency.

While only two sunlight receiving devices are combined for simplifying descriptions in the example of FIG. 8, any number of sunlight receiving devices may be combined; three sunlight receiving devices with their polarization directions differing from one another by 120 degrees may be combined. Also, the polarization directions may be two directions that are orthogonal to each other, two directions that are not orthogonal, or three or more different directions.

<<2.3 Wavelength/Frequency>>

Sunlight contains electromagnetic waves of different wavelengths or frequencies, specifically, wavelengths in the range from 200 nm to 2500 nm. Resonators such as the ones illustrated in FIG. 1, 7, or 8 have length λ/2 which is equal to one half of the fundamental resonance wavelength λ and resonate with electromagnetic waves of resonance wavelengths (λ(2n+1) and in the vicinity of λ). It follows that such a resonator is not able to derive energy from electromagnetic waves of the other wavelengths. This leads to the idea of deriving energy from sunlight over a wide wavelength range by combining multiple sunlight receiving devices having different resonator lengths.

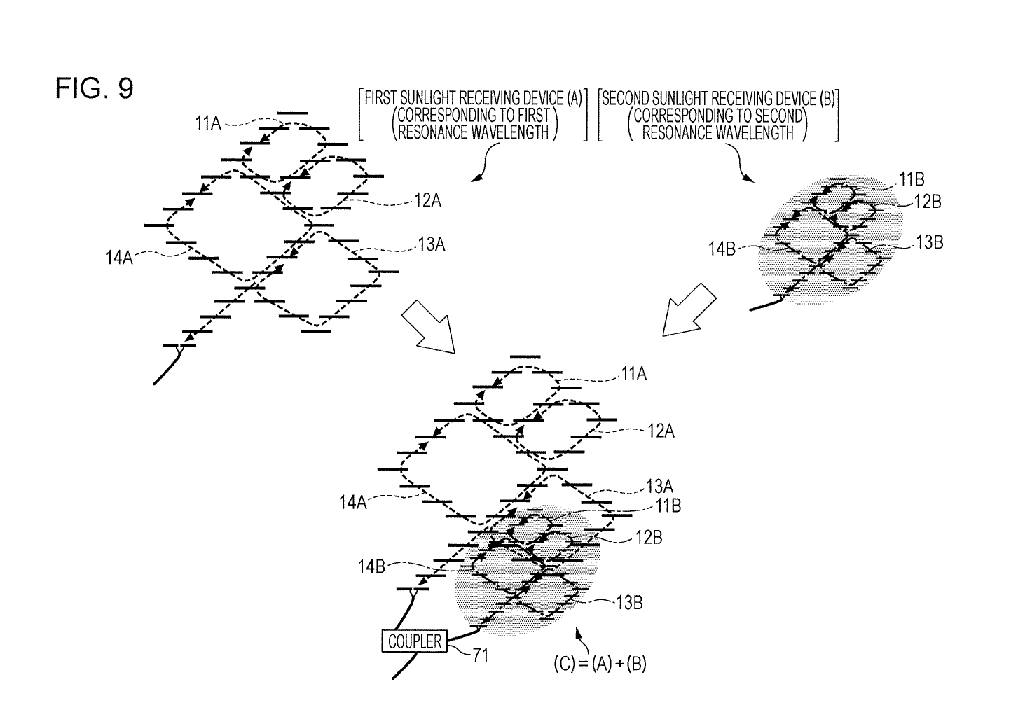

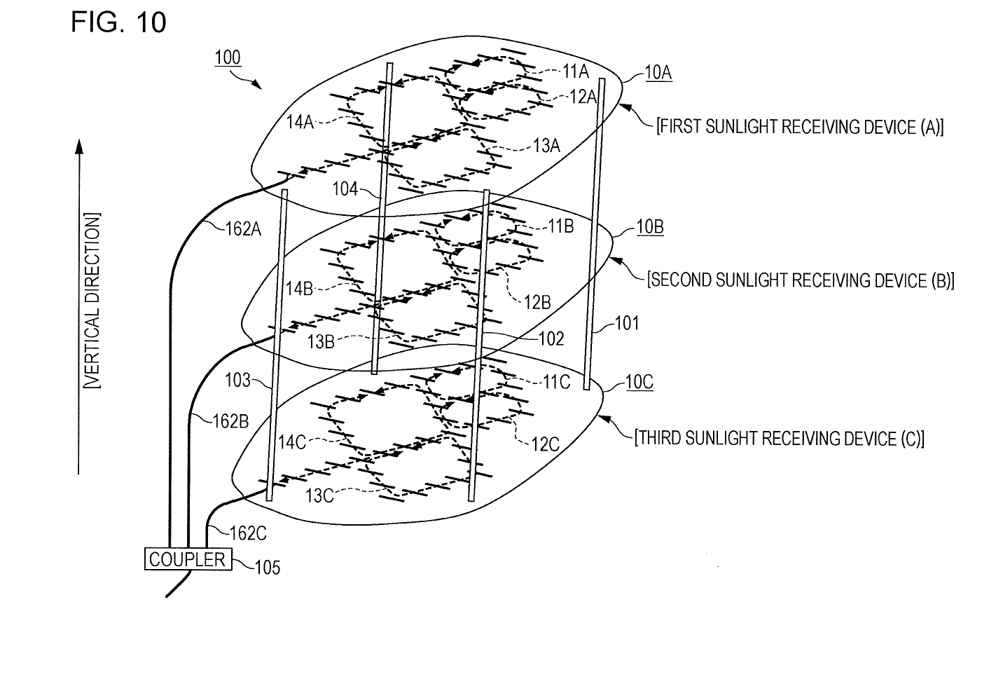

FIG. 9 illustrates a sunlight receiving system which combines two sunlight receiving devices corresponding to different resonance wavelengths. In the illustrated example, a first sunlight receiving device (A) whose fundamental resonance wavelength is a long wavelength λA and a second sunlight receiving device (B) whose fundamental resonance wavelength is a short wavelength λB are arranged on the same planar surface. Since resonators are provided on a substrate, “the same planar surface” may also be expressed as “the same substrate”. Alternatively, the two sunlight receiving devices (A) and (B) may be described as being present at heights that are substantially equal in vertical direction. The first sunlight receiving device (A) resonates with electromagnetic waves whose wavelength is a resonance wavelength (λA/(2n+1) and in the vicinity of λA) and is able to derive energy from it. The “vicinity” of a wavelength refers to a ±20% range around the wavelength herein, though a different range such as ±10% may be used. The first sunlight receiving device (A) is not able to derive energy from electromagnetic waves of the other wavelengths, however. Meanwhile, the second sunlight receiving device (B) resonates with electromagnetic waves of a different resonance wavelength (λB/(2n+1) and in the vicinity of λB) and is able to derive energy from it. Therefore, part of energy that may not be derived by first sunlight receiving device (A) may be derived by the second sunlight receiving device (B).

First, as illustrated in the upper left and right in FIG. 9, two sunlight receiving devices (A) and (B) corresponding to different resonance wavelengths may coexist without overlapping at all and electric power produced by them may be merged together. In this case, however, the entire sunlight receiving system occupies a large area, which is not preferable from the viewpoint of improvement in reception efficiency per unit area. Meanwhile, resonators and the like are not formed in an area defined by each loop included in a sunlight receiving device of the type illustrated in FIG. 1. It is thus not possible to receive sunlight incident in an area defined by a loop and produce energy from it. This leads to the idea of making the whole or part of at least one loop of the second sunlight receiving device (B) be included in the area defined by at least one loop of the first sunlight receiving device (A). This may increase the density of resonators forming loops and improve reception efficiency per unit area.

In the example illustrated in the lower portion of FIG. 9, a third loop 13A of the first sunlight receiving device (A) substantially coincides with the first loop 11B and the second loop 12B of the second sunlight receiving device (B) and partially overlaps the fourth loop 14B. The first and second sunlight receiving devices have different resonance wavelengths (or resonance frequencies). Energy from sunlight accordingly is not communicated between the first and the second sunlight receiving devices (A) and (B) but transferred only within the individual sunlight receiving devices (A) and (B), and power from the first and second sunlight receiving devices (A) and (B) is separately fed to the coupler 71 and merged therein. This may draw higher power from the coupler 71 than when the first or the second sunlight receiving device (A) or (B) is present singly. In this example, all resonators are present in an area smaller than when the first and second sunlight receiving devices (A) and (B) coexist without overlapping each other, which is preferable in terms of improving per-unit-area reception efficiency.

While only two sunlight receiving devices are combined in the example of FIG. 9 for simplifying descriptions, any number of sunlight receiving devices may be combined.

### 3. Three-Dimensional Sunlight Receiving System

<<3.1 Three-Dimensional Arrangement>>

While “2. Two-dimensional sunlight receiving system” above illustrates planar or two-dimensional combination of multiple sunlight receiving devices such as the one illustrated in FIG. 1, they may be combined sterically or three-dimensionally instead of planar combination. “Combining sterically” means forming a sunlight receiving system such that multiple sunlight receiving devices are provided at different positions in vertical direction (that is, at different heights). A sunlight receiving system combining multiple sunlight receiving devices sterically may include sunlight receiving devices corresponding to different polarization directions as described in Section 3.2 or sunlight receiving devices corresponding to different resonance wavelengths as described in Section 3.3. Sunlight receiving devices to be combined may be the same or different.

FIG. 10 illustrates an example of a sunlight receiving system 100 that sterically combines multiple sunlight receiving devices of the type illustrated in FIG. 1. The sunlight receiving system 100 includes the first, second, and third sunlight receiving devices (A), (B), (C), feed lines 162A, 162B, 162C, a coupler 105, and support members 102, 103, 104.

The first to third sunlight receiving devices (A) to (C) are sunlight receiving devices of the type illustrated in FIG. 1, being disposed at different positions in the vertical direction. In the first sunlight receiving device (A), resonators are provided on a substrate 10A such that they form the first loop 11A, the second loop 12A, the third loop 13A, and the fourth loop 14A. In the second sunlight receiving device (B), resonators are provided on a substrate 10B such that they form the first loop 11B, the second loop 12B, the third loop 13B, and the fourth loop 14B. In the third sunlight receiving device (C), resonators are provided on a substrate 10C such that that they form the first loop 11C, the second loop 12C, the third loop 13C, and the fourth loop 14C.

The feed lines 162A to 162C respectively transmit electric power produced by the first to third sunlight receiving devices (A) to (C) to the coupler 105.

The coupler 105 merges power transmitted from the feed lines 162A to 162C and sends the power to a rectifier and the like not illustrated.

The support members 102, 103, and 104 elastically or fixedly retain the relative positional relationship among the first to third sunlight receiving devices (A), (B), and (C). The support members 102 to 104 are not requisite as they are provided for the purpose of supplementing the mechanical strength of the sunlight receiving system. For example, if the first to third sunlight receiving devices (A), (B), and (C) are formed on thin flexible substrates, their positional relationship is preferably maintained by support members 102 to 104. In contrast, if the first to third sunlight receiving devices (A) to (C) are formed on thick substrates, support members 102 to 104 may be omitted because their positional relationship is already fixed.

In a case where the feed lines 162A to 162C are relatively hard coaxial cable (semi-rigid cable, for example), the feed lines 162A to 162C may serve as support members for retaining the relative positional relationship among the first to third sunlight receiving devices (A) to (C).

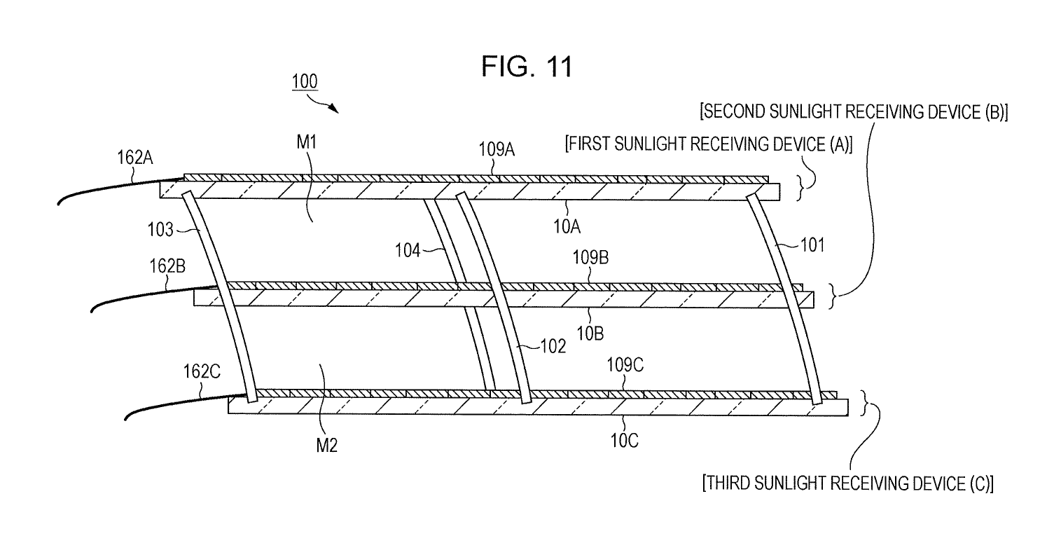

FIG. 11 is a side view of the sunlight receiving system 100. In FIG. 11, which does not depict the coupler 105, the first to third sunlight receiving devices (A) to (C) are disposed at different positions in the vertical direction. The first sunlight receiving device (A) includes at least the substrate 10A and multiple resonators 109A provided on the substrate 10A. The second sunlight receiving device (B) includes at least the substrate 10B and multiple resonators 109B provided on the substrate 10B. The third sunlight receiving device (C) includes at least the substrate 10C and multiple resonators 109C provided on the substrate 10C. Electric power gained from sunlight in the first sunlight receiving device (A) is transferred to the coupler 105 (FIG. 10) through the feed line 162A. Electric power gained from sunlight in the second sunlight receiving device (B) is transferred to the coupler 105 (FIG. 10) through the feed line 162B. Electric power gained from sunlight in the third sunlight receiving device (C) is transferred to the coupler 105 (FIG. 10) through the feed line 162C.

In the embodiment in FIG. 11, a gap or air layer is formed in portion M1 between the first sunlight receiving device (A) and the second sunlight receiving device (B). Provision of an air layer in the M1 portion is not requisite however; the M1 portion may be formed of a transparent dielectric layer, for example. Similarly, there is also a gap or an air layer in the portion M2 between the second sunlight receiving device (B) and the third sunlight receiving device (C). Provision of an air layer in the M2 portion is not requisite however; the M2 portion may be formed of a transparent dielectric layer, for example.

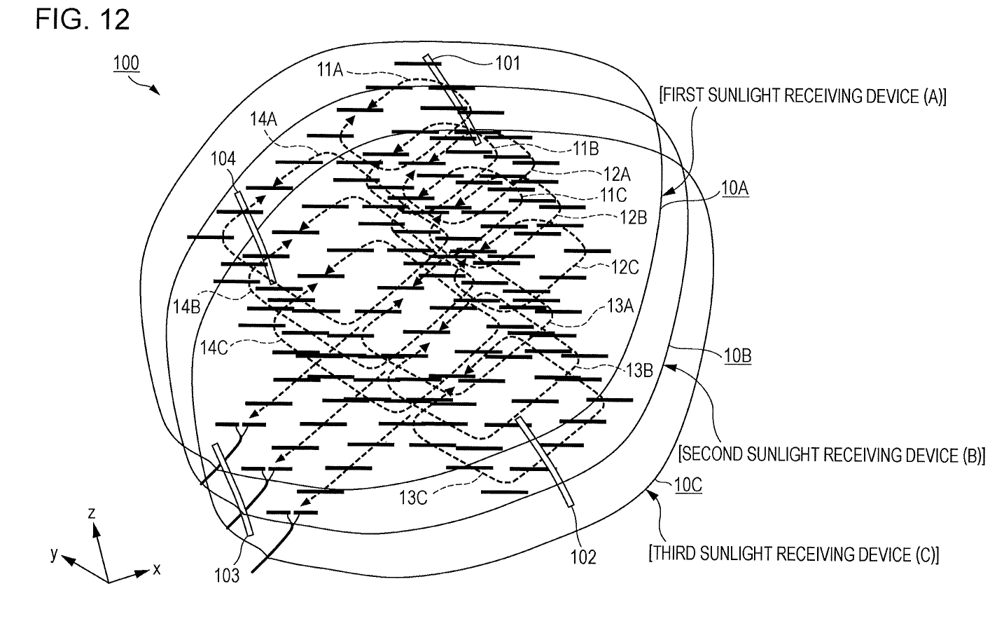

In the embodiment illustrated in FIGS. 10 and 11, although the first to third sunlight receiving devices (A) to (C) are arranged at regular intervals, regular spacing is not requisite but they may be provided at irregular intervals. It is not requisite either that the first to third sunlight receiving devices (A) to (C) be arranged in alignment in the direction, such as X axis or Y axis for example, perpendicular to the vertical direction (Z axis for example), though FIG. 12 depicts them as such. The sunlight receiving devices (A) to (C) may be arranged in the vertical direction in a positional relationship in which they are shifted from each other in the direction perpendicular to the vertical direction. This relies on the fact that sunlight may be incident on resonators not only vertically from above but obliquely.

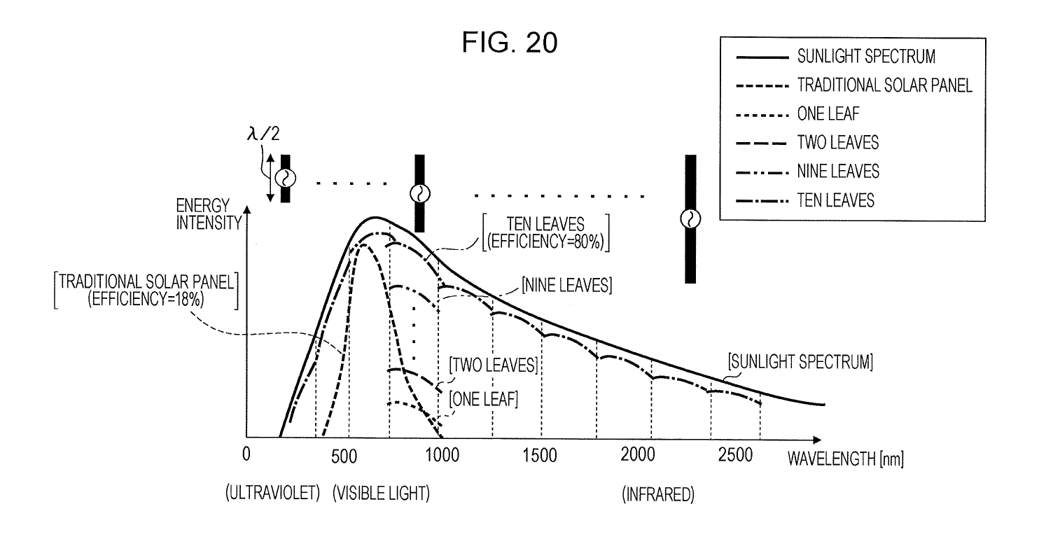

Assume that sunlight is incident on the sunlight receiving system 100 illustrated in FIG. 10, 11, or 12 vertically from above. When sunlight is incident on the first sunlight receiving device (A), resonators 109A of the first sunlight receiving device (A) resonate and produced electric power is sent to the coupler 105 through the feed line 162A. Sunlight that has not been received by the first sunlight receiving device (A) and escaped downward is incident on the second sunlight receiving device (B), which causes the resonators 109B of the second sunlight receiving device (B) to resonate and produced electric power is sent to the coupler 105 through the feed line 162B. Sunlight that has not been received by the second sunlight receiving device (B) either and escaped downward is incident on the third sunlight receiving device (C), which causes the resonators 109C of the third sunlight receiving device (C) to resonate and produced electric power is sent to the coupler 105 through the feed line 162C. Although the illustrated example uses three devices, namely the first to third sunlight receiving devices (A) to (C), this is not requisite; two, or four or more sunlight receiving devices may be used. The more sunlight receiving devices are provided in the vertical direction, more of sunlight escaping downward may be received, which will be described below with reference to FIG. 20.

As used herein, the term “above” is intended to mean directions that intersect with the vertical direction at a slant (that is, directions that form non-zero angles with the vertical direction) in addition to the direction parallel to the vertical direction. Likewise, the term “downward” is intended to mean directions that intersect with the vertical direction at a slant (that is, directions that form non-zero angles with the vertical direction) in addition to the direction parallel to the vertical direction.

The sunlight receiving system described in “2. Two-dimensional sunlight receiving system” improves per-unit-area reception efficiency by disposing multiple sunlight receiving devices on the same planar surface such that they overlap each other. In that case, the whole or part of at least one loop of one sunlight receiving device is included in an area defined by at least one loop of another sunlight receiving device. This is preferable from the viewpoint of improvement in reception efficiency per unit area, but may complicate manufacturing depending on the precision of microfabrication in forming resonator patterns because the number of resonators per unit area increases.

In contrast, when multiple sunlight receiving devices are disposed at different positions in the vertical direction as illustrated in FIGS. 10, 11, and 12, reception efficiency may be improved without increasing the number of resonators per unit area in each sunlight receiving device. This is because sunlight that is not received by a sunlight receiving device and escapes downward is at least partially received by a sunlight receiving device positioned below. In FIGS. 10, 11, and 12, the all or part of loops of the second sunlight receiving device (B) are positioned vertically below the areas defined by loops 11A to 14A of the first sunlight receiving device (A). Likewise, all or part of the loops of the first sunlight receiving device (A) are positioned vertically above the areas defined by the loops of the second sunlight receiving device (B), and all or part of the loops of the third sunlight receiving device (C) are positioned vertically below those areas. Finally, all or part of the loops of the second sunlight receiving device (B) are positioned vertically above the areas defined by the loops of the third sunlight receiving device (C).

<<3.2 Polarization>>

Just as described above in Section 2.2, at least two of multiple sunlight receiving devices may correspond to different polarization directions.

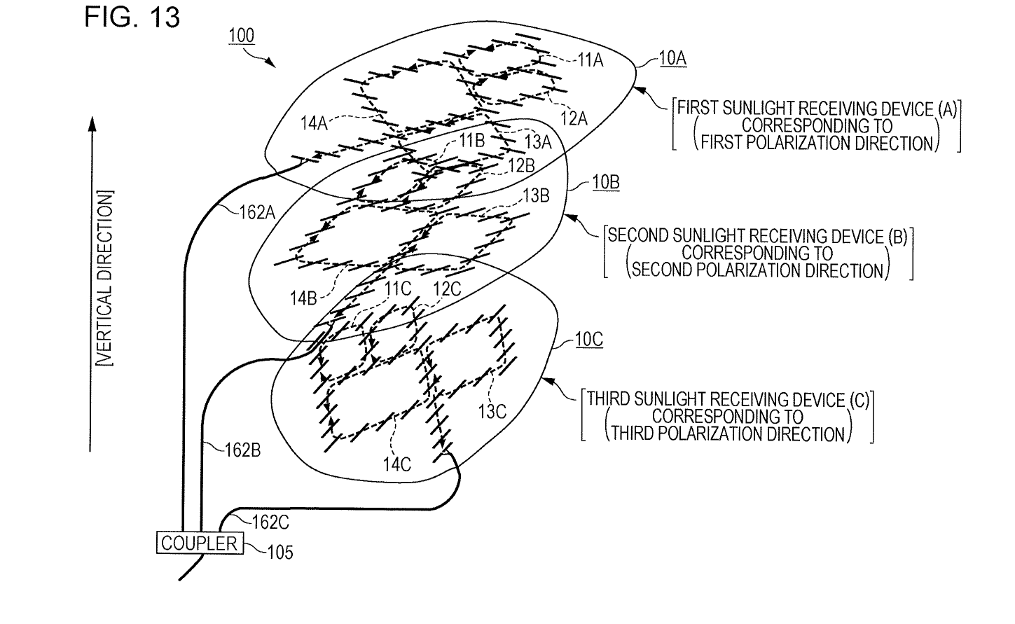

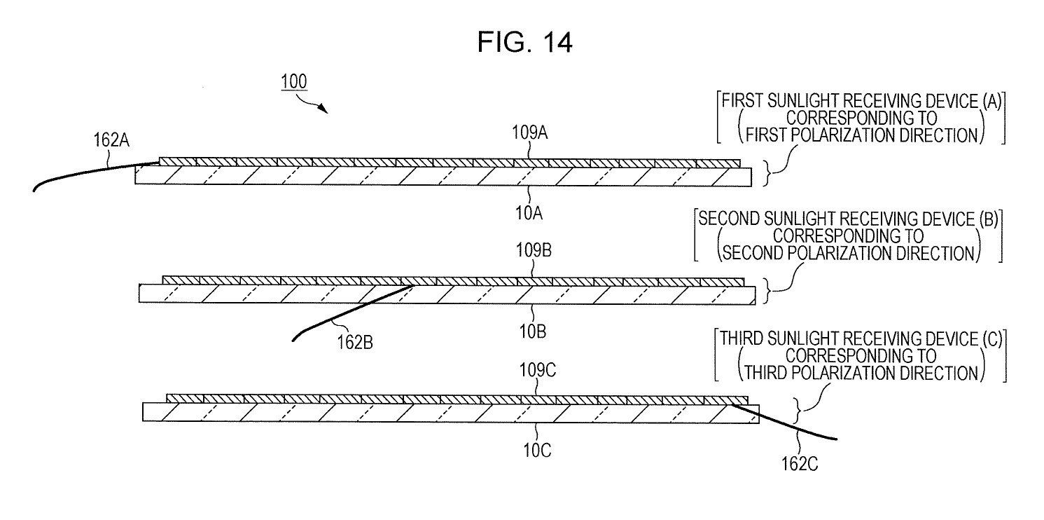

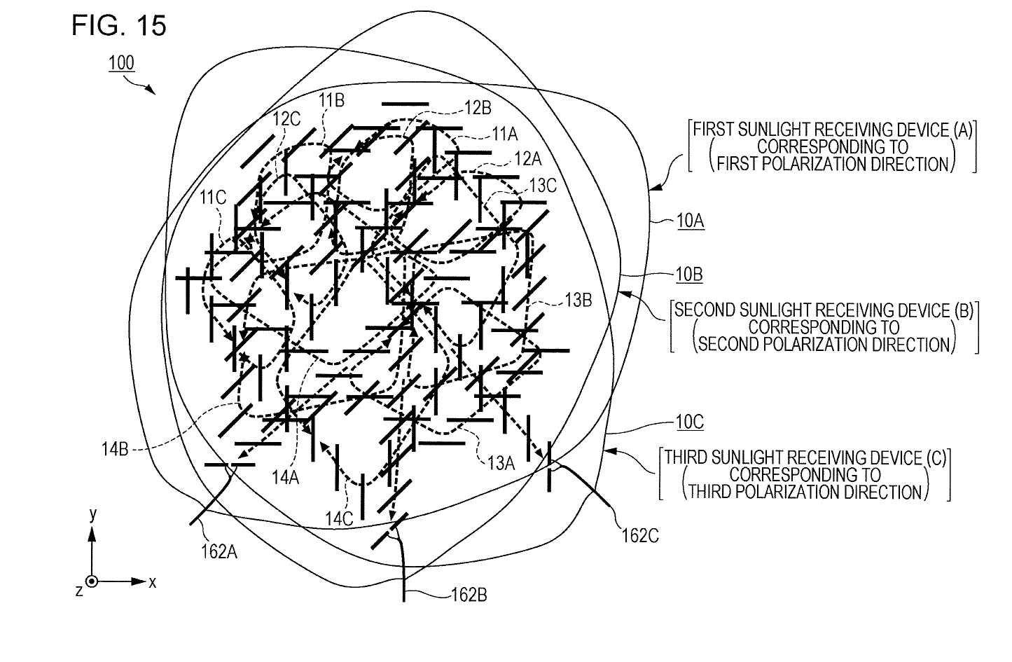

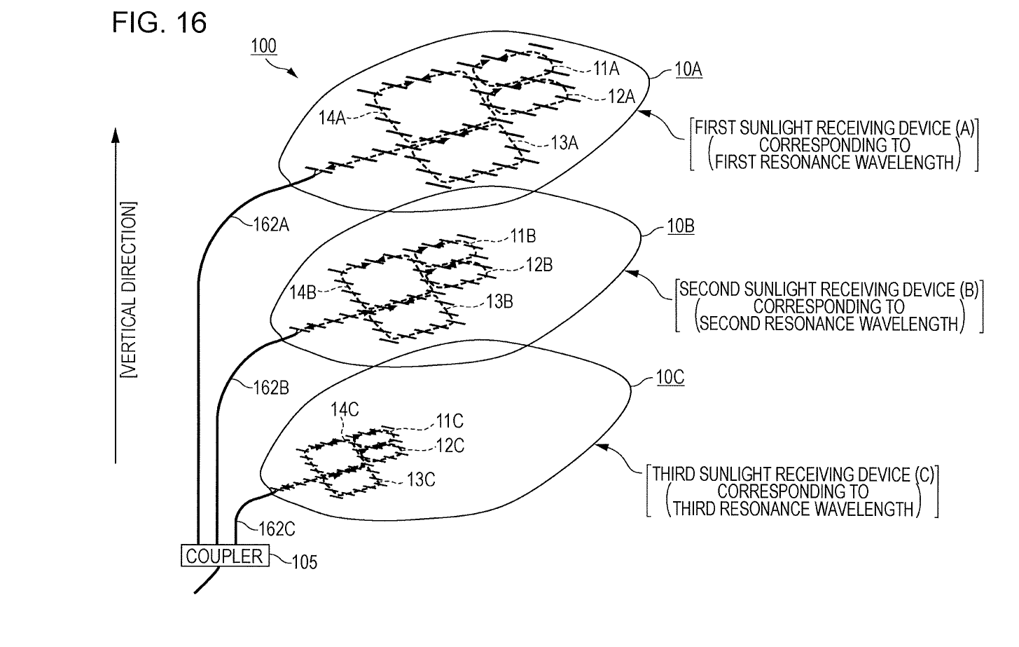

FIG. 13 illustrates a sunlight receiving system 100 in which three, or first to third sunlight receiving devices (A) to (C) corresponding to different polarization directions are combined. FIG. 14 is a side view of the sunlight receiving system 100 illustrated in FIG. 13. FIG. 15 is a top view of the sunlight receiving system 100 illustrated in FIG. 13.

Although generally similar to the example illustrated in FIGS. 10, 11, and 12, FIGS. 13 to 15 emphasize that the second sunlight receiving device (B) is equivalent to the first sunlight receiving device (A) as rotated about the vertical axis by a certain angle (120 degrees for instance). It is also emphasized that the third sunlight receiving device (C) is equivalent to the first sunlight receiving device (A) as rotated about the vertical axis by another certain angle (240 degrees for instance).

Assume that sunlight is incident on the sunlight receiving system 100 illustrated in FIGS. 13, 14, and 15 vertically from above. When sunlight is incident on the first sunlight receiving device (A) first, sunlight having the polarization direction of the first direction causes the resonators 109A of the first sunlight receiving device (A) to resonate, and produced electric power is sent to the coupler 105 through the feed line 162A. Of sunlight that has not been received by the first sunlight receiving device (A) and escaped downward, sunlight having the polarization direction of the second direction causes the resonators 109B of the second sunlight receiving device (B) to resonate, and produced electric power is sent to the coupler 105 through the feed line 162B. Further, of sunlight that has not been received by the second sunlight receiving device (B) and escaped downward, sunlight having the polarization direction of the third direction causes the resonators 109C of the third sunlight receiving device (C) to resonate, and produced electric power is sent to the coupler 105 through the feed line 162C.

<<3.3 Wavelength/Frequency>>

Just as described above in Section 2.3, at least two of multiple sunlight receiving devices may correspond to different resonance wavelengths (or resonance frequencies).

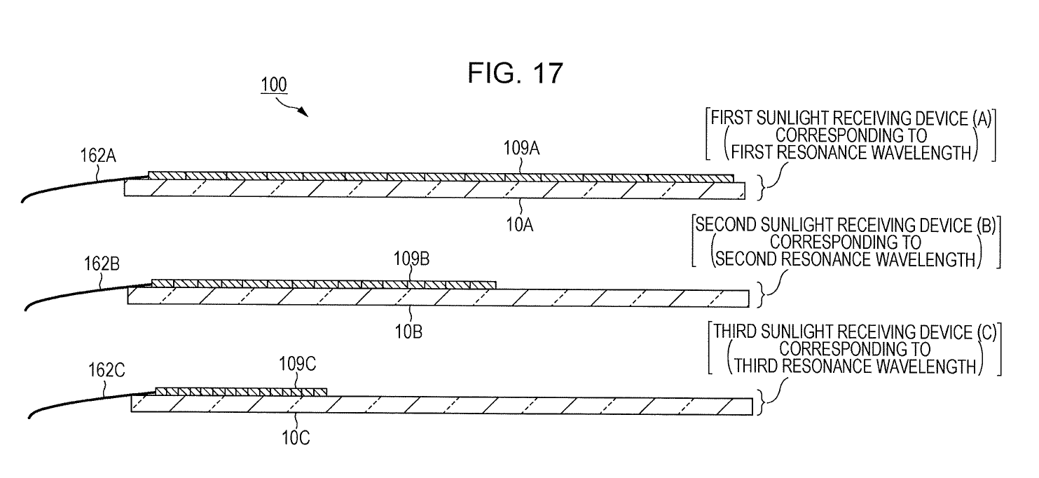

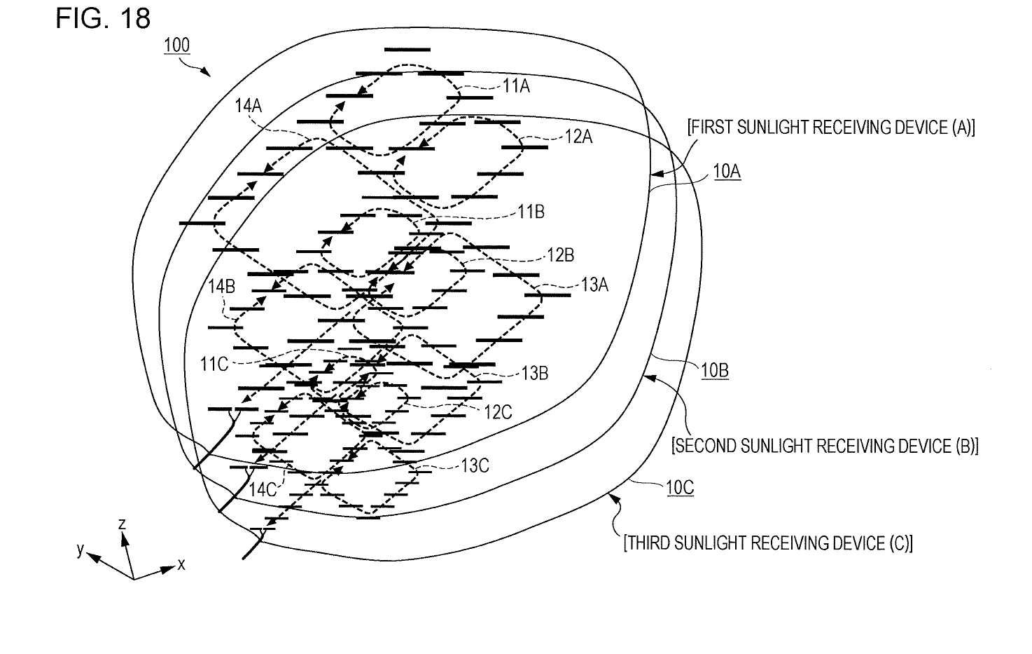

FIG. 16 illustrates a sunlight receiving system 100 that combines three, or first to third sunlight receiving devices (A) to (C) corresponding to different resonance wavelengths. FIG. 17 is a side view of the sunlight receiving system 100 illustrated in FIG. 16. FIG. 18 is a top view of the sunlight receiving system 100 illustrated in FIG. 16.

Although generally similar to the example illustrated in FIGS. 10, 11, and 12, FIGS. 16 to 18 emphasize that the fundamental resonance wavelengths of the first to third sunlight receiving devices (A) to (C) are first to third wavelengths λA, λB, and λC, respectively (where λA>λB>λC).

Assume that sunlight is incident on the sunlight receiving system 100 illustrated in FIGS. 16, 17, and 18 vertically from above. When sunlight is incident on the first sunlight receiving device (A) first, sunlight of the first resonance wavelengths (λA/(2n+1) and in the vicinity of λA) causes the resonators 109A of the first sunlight receiving device (A) to resonate, and produced electric power is sent to the coupler 105 through the feed line 162A. Of sunlight that has not been received by the first sunlight receiving device (A) and escaped downward, sunlight of the second resonance wavelengths (λB/(2n+1) and in the vicinity of λB) causes the resonators 109B of the second sunlight receiving device (B) to resonate, and produced electric power is sent to the coupler 105 through the feed line 162B. Further, of sunlight that has not been received by the second sunlight receiving device (B) and escaped downward, sunlight of the third resonance wavelengths (λC/(2n+1) and in the vicinity of λC) causes the resonators 109C of the third sunlight receiving device (C) to resonate, and produced electric power is sent to the coupler 105 through the feed line 162C.

### 4. Applications

<<4.1 Tree Structure>>

The sunlight receiving device illustrated in FIG. 1 or the sunlight receiving systems illustrated in FIGS. 7 through 18 may be used singly or in combination.

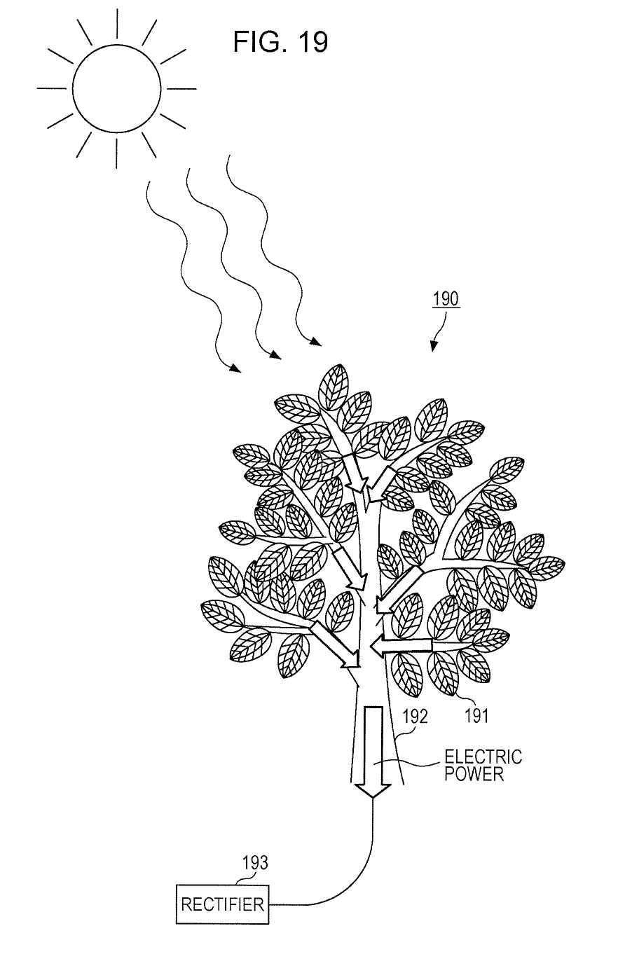

FIG. 19 illustrates a light receiving system 190 in which multiple power feeding units (161 in FIG. 1, for example) coupled to multiple sunlight receiving devices or sunlight receiving systems 191, which may be generally referred to as “element” as appropriate hereinafter, are connected with an electrically conductive channel 192 which branches like a tree. Many elements 191 depicted in FIG. 19 like tree leaves include sunlight receiving devices of the type illustrated in FIG. 1 or sunlight receiving systems of the types illustrated in FIGS. 7 through 18. If transparent flexible substrates having a thickness of about 0.1 mm are used in the sunlight receiving devices or sunlight receiving systems, the elements 191 may be formed like tree leaves. These elements 191 are referred to as “leaf” or “leaves”. That is, the term “element” may be interchangeably used with the terms “leaf” and “leaves”. As illustrated, a leaf 191 is coupled with a “branch” portion branching from a “trunk” like a tree, where electric power produced by light reception at the leaf 191 flows through branches and power from many branches meets at the trunk and is fed to a rectifier 193. The branch and trunk portions thus function as couplers to merge electric power. Through the rectifier 193, alternating-current energy from sunlight may be gained as direct-current energy. The gained energy may be fed to a storage battery or some load device and the like. The rectifier 193 is not requisite and alternating-current energy may be fed to some other device.

Although leaves 191 that form leaf-like shapes are connected to a trunk and branches that form a tree-like shape in the embodiment in FIG. 19, this formation is not requisite; any shape appropriate for receiving sunlight may be used in the light receiving system. The formation illustrated in FIG. 19 is advantageous in that it does not look awkward when the light receiving system is installed on a house roof or in a garden. The light receiving system may be installed in not only the outdoor but also in any appropriate place where it may receive sunlight.

<<4.2 Reception Efficiency>>

FIG. 20 illustrates a relationship between a received sunlight wave length and output energy per unit area from the solar panel to compare between reception efficiency of when sunlight is received using the leaf (or element or leaves) described above and that of a traditional solar panel. In FIG. 20, the horizontal axis represents wavelength (nm) and the vertical axis represents energy intensity. The solid line indicates sunlight spectrum. Accordingly, it is represented that reception efficiency improves as the energy intensity at the time of reception at leaves or solar panel approaches the solid-line sunlight spectrum; whereas reception efficiency lowers as the intensity of received energy deviates from the solid-line sunlight spectrum.

A traditional solar panel utilizing the photoelectric effect of sunlight in the visible light range exhibits high energy intensity especially for wavelengths from 500 nm to 750 nm in the visible light range wavelengths (360 nm to 830 nm) as illustrated. Sunlight of the other wavelengths contained in the entire sunlight is not effectively received, however. As a result, the reception efficiency of the traditional solar panel is only about 18%.

“One leaf” in FIG. 20 indicates energy intensity yielded when sunlight is received using a single leaf, which was described in “4.1 Tree structure” above. The resonators of a sunlight receiving device (FIG. 1 or 7) or sunlight receiving system (FIGS. 10 to 18) included in the leaf are each designed to have a length of about 438 nm (875 nm÷2). Resonance wavelengths at which the resonators resonate includes wavelengths in the vicinity of the fundamental resonance wavelength λ. “Vicinity” means±about 20% herein, though a different value such as ±10% may be used. Accordingly, when the fundamental resonance wavelength of a resonator is 875 nm, the resonator resonates at wavelengths ranging from 700 (=850×0.8) nm to 1050 (=875×1.2) nm and is able to receive sunlight in that wavelength range. As illustrated, in the case of one leaf, energy intensity of received sunlight is fairly low and reception efficiency is only about 15%.

“Two leaves” in FIG. 20 indicates the energy intensity yielded when sunlight is received with combination of two leaves, each of which represents the “one leaf” above. While the two leaves are combined three-dimensionally as described in Section 3, they may be combined two-dimensionally as described in Section 2. The energy intensity of sunlight that may be received with two leaves is higher than when one leaf is used as illustrated, but the reception efficiency is still only about 30%.

“Nine leaves” in FIG. 20 indicates the energy intensity yielded when sunlight is received with combination of nine leaves, each of which represents the “one leaf” above. Again, while the nine leaves are combined three-dimensionally as described in Section 3, they may be combined two-dimensionally as described in Section 2. As illustrated, the energy intensity of sunlight that may be received with nine leaves is fairly high, achieving a reception efficiency of about 75%.

“Ten leaves” in FIG. 20 indicates the energy intensity yielded when sunlight is received with combination of ten leaves, each of which represents the “one leaf” above. Again, while the ten leaves are combined three-dimensionally as described in Section 3, they may be combined two-dimensionally as described in Section 2. As illustrated, the energy intensity of sunlight that may be received in the wavelength range from 700 nm to 1050 nm is high enough to approach the energy intensity of the sunlight spectrum. In order to further produce a light receiving system that resonates at other wavelengths, the wavelengths contained in sunlight are divided into ten ranges, and sunlight receiving devices or sunlight receiving systems are produced for each of the ten wavelength ranges, thereby creating one leaf. A light receiving system combining ten such leaves two- or three-dimensionally was created for each wavelength range, and energy intensity was measured for each wavelength range. As indicated at “ten leaves” in FIG. 20, the energy density of sunlight that could be received is close to the sunlight spectrum in all the wavelength ranges, and reception efficiency as high as about 80% is achieved. Theoretically, reception efficiency may be increased to near 100% by increasing the number of leaves to be combined.

According to the embodiments described above, use of a sunlight receiving device or a sunlight receiving system or a light receiving system in which such sunlight receiving devices or sunlight receiving systems are combined enables efficient reception of many electromagnetic waves (sunlight) having different wavelengths and polarization components. Such a light receiving system is advantageous in that it is simple in structure and high in reception efficiency.

While embodiments for receiving sunlight of particular wavelengths and/or polarizations have been described, the contents of the present disclosure are not limited to those embodiments; various variations, modifications, alternatives, replacements, and the like may occur to those skilled in the art. The disclosed embodiments may be applied to any appropriate device or system for receiving sunlight. While specific examples of numerical values were used for facilitating understanding of the embodiments, such numerical values are merely examples unless otherwise specified and any appropriate values may be used instead. For example, substrate thickness, the number of resonators, the number of loops, resonator dimensions, the number of sunlight receiving devices, and the like may be any appropriate values. The categorization of the sections used in the above description is not intrinsic to the disclosed embodiments. Matters described in two or more sections may be used in combination as desired, or a matter described in one section may be applied to a matter described in another section (as long as they are consistent with each other).

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A sunlight receiving device comprising:
a substrate; and
a plurality of resonators arranged on a surface of the substrate at certain intervals so as to form one of a plurality of loops, the plurality of loops partially bordering with each other, each one of the plurality of resonators having a length that resonates with sunlight of a certain wavelength;
wherein energy of the sunlight is obtained via a resonator that belongs to one or more of the plurality of loops, the resonator being one of the plurality of resonators.

2. The sunlight receiving device according to claim 1, wherein the plurality of loops includes commonly one or more resonator if the plurality of resonators so as to partially border with each other.

3. A sunlight receiving system comprising a plurality of sunlight receiving devices that are provided at a virtually same height in vertical direction,
wherein each one of the plurality of sunlight receiving devices includes
a substrate, and
a plurality of resonators arranged on a surface of the substrate at certain intervals so as to form a plurality of loops that partially border with each other, each one of the plurality of resonators having a length that causes resonance with sunlight of a predetermined wavelength,
wherein energy of the sunlight is obtained via a predetermined resonator that belongs to one or more of the plurality of loops.

4. The sunlight receiving system according to claim 3,
wherein a plurality of resonators in at least one of the plurality of sunlight receiving devices are disposed so as to resonate with a polarized wave for which an amplitude direction of an electric field or a magnetic field is a first direction, and
wherein a plurality of resonators in at least another one of the plurality of sunlight receiving devices are disposed so as to resonate with a polarized wave for which the amplitude direction of an electric field or a magnetic field is a second direction different from the first direction.

5. The sunlight receiving system according to claim 3,
wherein a plurality of resonators in at least one of the plurality of sunlight receiving devices each have a length that causes resonance with sunlight of a first wavelength, and
wherein a plurality of resonators in at least another one of the plurality of sunlight receiving devices each have a length that causes resonance with sunlight of a second wavelength different from the first wavelength.

6. A sunlight receiving system comprising a plurality of sunlight receiving devices provided at different heights in vertical direction,
wherein each one of the plurality of sunlight receiving devices includes
a substrate, and
a plurality of resonators arranged on a surface of the substrate at predetermined intervals so as to form a plurality of loops that partially border with each other,
wherein each one of the plurality of resonators has a length that causes resonance with sunlight of a predetermined wavelength, and
wherein energy of the sunlight is fetched via a predetermined resonator that belongs to one or more of the plurality of loops.

7. The sunlight receiving system according to claim 6,
wherein each one of the plurality of resonators included in a sunlight receiving device provided at a first height among the plurality of sunlight receiving devices is disposed so as to resonate with a polarized wave for which an amplitude direction of an electric field or a magnetic field is a first direction, and
wherein each one of the plurality of resonators included in a sunlight receiving device provided at a second height different from the first height among the plurality of sunlight receiving devices is disposed so as to resonate with a polarized wave for which the amplitude direction of an electric field or a magnetic field is a second direction different from the first direction.

8. The sunlight receiving system according to claim 6,
wherein each one of the plurality of resonators included in a sunlight receiving device provided at a first height among the plurality of sunlight receiving devices has a length that causes resonance with sunlight of a first wavelength, and
wherein each one of the plurality of resonators included in a sunlight receiving device provided at a second height different from the first height among the plurality of sunlight receiving devices has a length that causes resonance with sunlight of a second wavelength different from the first wavelength.

9. The sunlight receiving system according to claim 6, wherein a plurality of power feeding units connected with the plurality of sunlight receiving devices are connected to an electrically conductive channel that branches in a tree-like manner.

10. The sunlight receiving device according to claim 1, wherein the substrate is a transparent dielectric substrate that transmits the sunlight.

11. The sunlight receiving device according to claim 1, wherein the surface of the substrate defines a plane.

12. The sunlight receiving device according to claim 1, wherein the length of each one of the plurality of resonators is equal to one half of the predetermined wavelength.

13. The sunlight receiving device according to claim 1, wherein neighboring resonators in one or more loops among the plurality of loops are arranged in parallel with each other in a positional relationship in which the neighboring resonators are shifted from each other by a length equal to one quarter of the wavelength.

14. The sunlight receiving device according to claim 13, wherein the neighboring resonators are arranged in parallel with each other in a positional relationship in which the neighboring resonators are shifted from each other by a length equal to one half of the wavelength and are separated from each other by a distance equal to one quarter of the wavelength.

15. The sunlight receiving device according to claim 1, wherein one or more resonators that are arranged at the predetermined intervals so as not to form a loop between the predetermined resonator and a power feeding unit are also provided on the surface of the substrate.

16. The sunlight receiving system according to claim 3, wherein the plurality of sunlight receiving devices include at least first and second sunlight receiving devices, and a whole or part of at least one loop of the second sunlight receiving device is included in an area defined by at least one loop of the first sunlight receiving device.

17. The sunlight receiving system according to claim 6, wherein the plurality of sunlight receiving devices include at least first and second sunlight receiving devices, and a whole or part of at least one loop of the second sunlight receiving device is positioned vertically above or vertically below an area defined by at least one loop of the first sunlight receiving device.
